(19) United States
(12) Patent Application Publication
(10) Pub. No.: US 2026/0006805 A1
(43) Pub. Date: Jan. 1, 2026

(54) SEMICONDUCTOR STRUCTURE INCLUDING DEEP TRENCH CAPACITORS AND METHODS OF FABRICATION THEREOF

(71) Applicant: TAIWAN SEMICONDUCTOR MANUFACTURING COMPANY, LTD., Hsinchu (TW)

(72) Inventors: Tzu Jung TIEN, Hsinchu (TW); Cheung CHENG, Hsinchu (TW); Chen-Hsuan YEN, Taichung (TW); Fu-Chiang KUO, Hsinchu (TW)

(21) Appl. No.: 18/755,857

(22) Filed: Jun. 27, 2024

(51) Int. Cl. H10D 1/00; H10D 1/68

(52) U.S. Cl. CPC H10D 1/042; H10D 1/714; H10D 1/716

(57) ABSTRACT

In an embodiment, a semiconductor structure includes a substrate having a plurality of deep trenches oriented in a first direction and a second direction and a plurality of mesas interposed by the deep trenches. The semiconductor structure also includes a plurality of capacitor groups, wherein each of the capacitor groups includes a stack of conductive layers and node dielectric layers alternately disposed in the deep trenches and a first conductive plug disposed on a first layer of the conductive layers. The semiconductor structure also includes an isolation wall penetrating through the stack of the conductive layers and the node dielectric layers and into at least one of the mesas, the isolation wall being a close loop in a top view.

### BACKGROUND

Capacitors are used in semiconductor chips for many applications such as power supply stabilization. However, a significant amount of device area is often used to fabricate such capacitors. Accordingly, capacitors that may provide high capacitance with a small device footprint are desirable.

### BRIEF DESCRIPTION OF THE DRAWINGS

Aspects of the present disclosure are best understood from the following detailed description when read with the accompanying Figures. It is noted that, in accordance with the standard practice in the industry, various features are not drawn to scale. In fact, the dimensions of the various features may be arbitrarily increased or reduced for clarity of discussion.

FIG. 1 is a schematic diagram illustrating an example semiconductor package in accordance with some embodiments.

FIGS. 2 and 3 are top views of a deep-trench-capacitor (DTC) structure in accordance with some embodiments of the present disclosure.

FIGS. 4 to 7 illustrate a method for manufacturing a deep-trench-capacitor (DTC) structure at various stages in accordance with some embodiments of the present disclosure.

FIGS. 8 to 10 are top views of a deep-trench-capacitor (DTC) structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Capacitors are used for a myriad of purposes on modern integrated circuits (IC). For example, decoupling capacitors are used to decouple one part of an electrical circuit, such as interconnect, from another part of the circuit. In such a configuration, noise arising from the interconnect can be shunted through a decoupling capacitor to reduce the effects of interconnect noise on the remainder of the circuit. Since such capacitors are often placed close to the circuit to eliminate parasitic inductances and resistances associated with the interconnect, there is a need to create a high-density capacitor in either the IC technology of interest or in a stand-alone process that results in an integrated capacitor device easily mountable on the IC.

The miniaturization of devices on modern integrated circuits resulted in challenges for circuit designers dealing with power delivery networks (PDNs, also known as power distribution networks). The last decade saw the rise of non-planar devices (e.g., FinFET or nano-FETs), bringing higher drive strengths compared to the planar devices. The use of non-planar devices increases the drive strength per unit area, requiring higher current densities and larger current transients. This trend has resulted in chips that are increasingly sensitive to fluctuating supply voltages, exacerbating the power integrity challenges of system design. Circuit designers rely on decoupling capacitors as a fundamental tool for reducing the impedance of PDNs and suppressing noise by decoupling or bypassing one part of a circuit from another. For signals, noise from the interconnect can be shunted through a decoupling capacitor before being passed to another circuit. However, decoupling capacitors are generally physically located in close proximity to the desired circuit in order to reduce parasitic resistances and inductances.

On the other hand, packaging technologies are evolving rapidly, providing more platforms where advanced capacitor technologies can be employed. As will be described below, advanced capacitor technologies may be used in advanced packaging technologies such as Chip-on-Wafer-on-Substrate (CoWoS) and System on Integrated Chips (SoIC) technologies. These advanced packaging technologies enable the application of advanced capacitor technologies.

Packaging technologies were once considered just back-end processes, almost an inconvenience. Times have changed. Computing workloads have evolved more over the past decade than perhaps the previous four decades. Cloud computing, big data analytics, artificial intelligence (AI), neural network training, AI inferencing, mobile computing on advanced smartphones, and even self-driving cars are all pushing the computing envelope. Modern workloads have brought packaging technologies to the forefront of innovation, and they are critical to a product's performance, function, and cost. These modern workloads have pushed the product design to embrace a more holistic approach for optimization at the system level.

Chip-on-Wafer-on-Substrate (CoWoS) is a wafer-level multi-chip packaging technology. CoWoS is a packaging technology that incorporates multiple chips side-by-side on a silicon interposer in order to achieve better interconnect density and performance. Individual chips are bonded through, for example, micro-bumps on a silicon interposer, forming a chip-on-wafer (CoW) structure. The CoW structure is then subsequently thinner such that through-silicon-vias (TSVs) are exposed, which is followed by the formation of bumps (e.g., C4 bumps) and singulation. The CoW structure is then bonded to a package substrate forming the CoWoS structure. Since multiple chips or dies are generally incorporated in a side-by-side manner, the CoWoS is considered a 2.5-dimensional (2.5D) wafer-level packaging technology.

On the other hand, those multiple chips bonded to the interposer in the CoWoS structure can each include stacking dies or chiplets (i.e., modular dies), with multi-layers, multi-chip sizes, and multi-functions. In one implementation, the stacking dies are bonded together using a direct bonding technique. The direct bonding is a bumpless bonding technique that includes directly bonding dielectric layers and directly bonding metal pads, which can provide improved integration density, faster speeds, and higher bandwidth. In addition to die-to-die bonding, the direct bonding technique may be used for wafer-to-wafer bonding and die-to-wafer bonding.

Stacking dies featuring ultra-high-density-vertical stacking is sometimes referred to as System on Integrated Chips (SoIC) technologies. SoIC technologies can achieve high performance, low power, and minimum resistance-inductance-capacitance (RLC). SoIC technologies integrate active and passive chips that are partitioned from System on Chip (SoC), into a new integrated SoC system, which is electrically identical to native SoC, to achieve better form factor and performance. A die stack bonded together using hybrid bonding is sometimes, therefore, referred to as a SoIC die stack (“SoIC die stack” and “die stack” are used interchangeably throughout the disclosure).

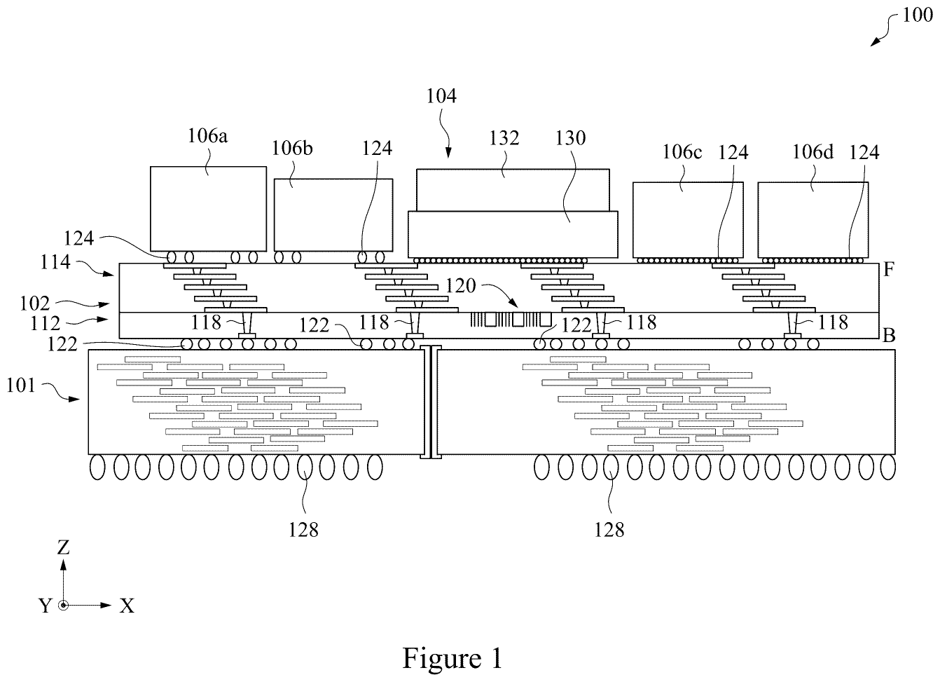

FIG. 1 is a schematic diagram illustrating an example semiconductor package in accordance with some embodiments. Shown here is a semiconductor package 100. In the example shown in FIG. 1, the semiconductor package 100 includes an interposer 102, a die stack 104 (e.g., SoIC die stack), and multiple chips 106a, 106b, 106c, 106d, among other components. The die stack 104 and the multiple chips 106a-106d are located on and bonded to the top surface of the interposer 102 in the vertical direction (i.e., the Z-direction, as shown in FIG. 1). The die stack 104 and the multiple chips 106a-106d are located at various locations in the horizontal plane (i.e., the X-Y plane, as shown in FIG. 1) in a side-by-side manner. The interposer 102 is further bonded to a package substrate 101.

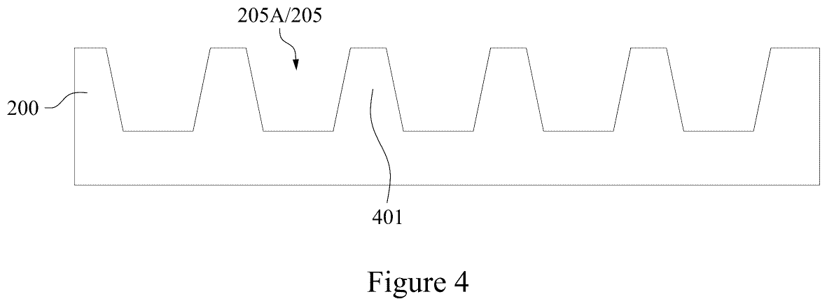

The interposer 102 provides an interfacial substrate between the package substrate 101 and either the die stack 104 or the multiple chips 106a-106d. In some embodiments, the package substrate 101 is bonded to another substrate, such as a printed circuit board (PCB). In the example shown in FIG. 1, the interposer 102 includes a substrate section 112 and an interposer multilayer interconnect (MLI) structure 114. In one embodiment, the substrate section 112 is a silicon substrate. The substrate section 112 includes one or more through-silicon vias (TSVs) 118 through the substrate section 112. In the example shown in FIG. 1, a deep trench capacitor (DTC) structure 120 is disposed in the substrate section 112, and a portion of or the entire DTC structure 120 can be electrically connected to one or more of the die stacks 104 and the chips 106a-106d. Details of the DTC structure 120 will be described below with reference to FIGS. 4 to 7. It should be understood that the semiconductor package 100 shown in FIG. 1 is one example of many applications of the DTC structure 120.

In addition, the interposer 102 shown in FIG. 1 also includes bumps 122 (e.g., solder bumps, C4 bumps, etc.) and micro-bumps 124. At the back side (denoted as “B” in FIG. 1) of the interposer 102, the bumps are used to bond the interposer 102 to the package substrate 101. It should be understood that the bumps 122 is exemplary rather than limiting, and other types of bonding techniques may be employed in other implementations. In some embodiments, each of the TSVs 118 is electrically connected to at least one bump 122.

At the front side (denoted as “F” in FIG. 1) of the interposer 102, the micro-bumps 124 are used to bond the chips 106a-106d to the interposer 102. It should be understood that micro-bumps are exemplary rather than limiting, and other types of bonding techniques may be employed in other implementations. As to the interface between the interposer 102 and the die stack 104, the die stack 104 can be bonded to the interposer 102 using a direct bonding technique in one implementation. In other implementations, the die stack 104 can be bonded to the interposer 102 using other bonding techniques, such as the micro-bumps.

As a result, the package substrate 101 can be electrically connected to one or more of the die stacks 104 and the chips 106a-106d through the interposer 102. An exemplary electrical path includes the bump 122, the TSV 118, the MLI structure 114, and the micro-bump 124.

In the example shown in FIG. 1, the die stack 104 includes a bottom die 130 and a top die 132. A bonding layer is formed on the top surface of the bottom die 130, and another bonding layer is formed on the bottom surface of the top die 132. Those bonding layers are made of a dielectric (e.g., silicon oxide) and used for bonding the top die 132 to the bottom die 130. Pairs of metal bonding pads are formed in those bonding layers. When the top die 132 and the bottom die 130 are bonded together, each pair of metal bonding pads is aligned in the X-Y plane and in contact with each other, providing an electrical path between the bottom die 130 and the top die 132. As the metal bonding pads can have small critical dimensions and pitches, the die stack 104 can achieve better interconnect density and performance (e.g., faster speeds, higher bandwidth, and the like). In some embodiments, the chips 106a-106d are independent chips, which fulfill various functions. Each of the chips 106a-106d is one of, for example, a logic chip, a memory chip, a computation chip, a sensor chip, a radio frequency (RF) chip, a high voltage (HV) chip, and the like.

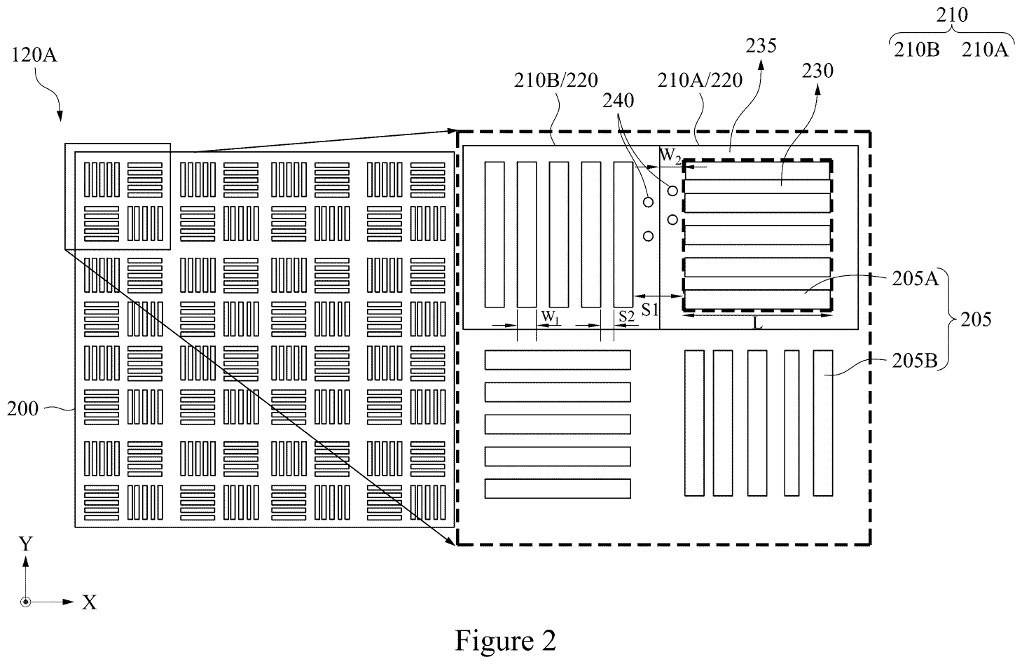

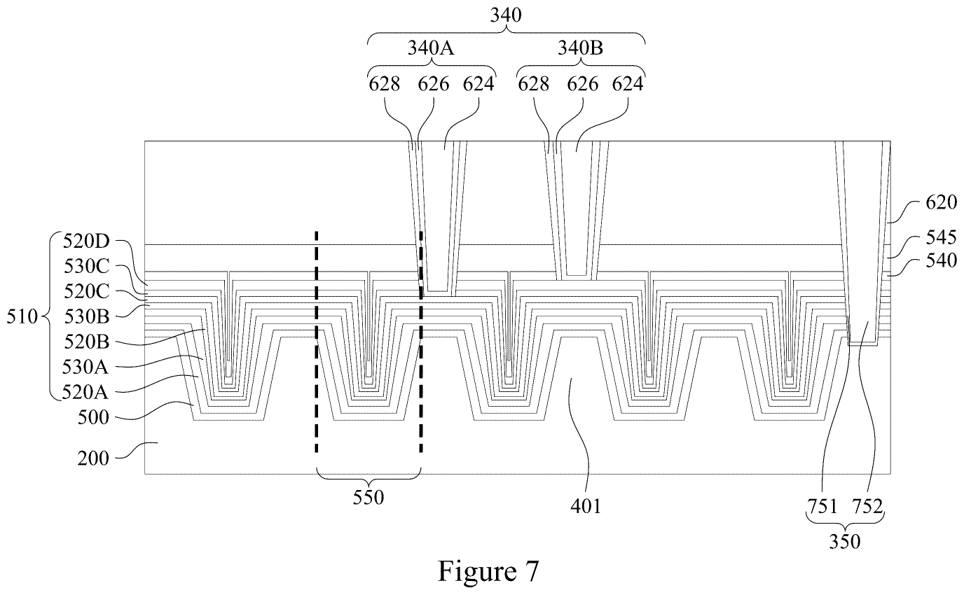

FIG. 2 is a top view of a deep trench capacitor (DTC) structure in accordance with some embodiments. The DTC structure 120A may serve as the DTC structure 120 of FIG. 1. The DTC structure 120A includes a plurality of capacitor units (see FIG. 7). The DTC structure 120A may include a plurality of dielectric layers (see FIG. 7) and a plurality of conductive layers (see FIG. 7) formed in a plurality of deep trenches to form the capacitors. The dielectric layers and the conductive layers are not shown in FIG. 2 for clarity purposes. In some embodiments, the DTC structure 120A is formed in a substrate 200. The substrate 200 may be the interposer 102 as illustrated in FIG. 1 or any suitable substrate in a chip or in a package. In some embodiments, the substrate 200 includes a crystalline semiconductor material such as, but not limited to, silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In one embodiment, the substrate 200 is made of silicon. In some embodiments, the substrate 200 is a silicon-on-insulator (SOI) substrate having an insulating layer (not shown) disposed between two silicon layers for enhancement. In one aspect, the insulating layer is an oxygen-containing layer.

Deep trenches 205 are formed in the substrate 200. The deep trenches 205 may extend from a top surface of the substrate 200 into the substrate 200. The deep trenches 205 may have vertical or tilt sidewalls. As shown in FIG. 2, the deep trenches 205 may have a width W₁ (or a bottom width W₁ of the deep trenches 205 when the sidewalls are tilt) and a length L. In some embodiments, at each of the deep trenches 205 are laterally elongated with a substantially uniform width, although some of them may have different widths for design purposes. The width W₁ of the deep trenches 205 may be sufficiently wide to accommodate the conductive layers and the dielectric layers. The length L may be greater than the width W₁. In some embodiments, the width W₁ is in a range from about 10 nm to about 2000 nm, and the length Lis in a range from about 1 μm to about 10 μm. In some embodiments, the deep trenches 205 have a length-to-width ratio ranging from about 100 to about 1000. In some embodiments, the deep trenches 205 have a depth-to-width ratio ranging from about 10 to about 200. Although only a rectangular shape is illustrated in FIG. 2, the deep trenches 205 may each have a shape of a circle, an ellipse, a rounded rectangle, an annulus having an inner periphery and an outer periphery of various shapes in the top view, or of any two-dimensional shape that defines an enclosed volume.

The deep trenches 205 may include first deep trenches 205A and second deep trenches 205B. As shown in FIG. 2, the first deep trenches 205A has a lengthwise direction extending along a first direction (e.g., X-direction), and the second deep trenches 205B have a lengthwise direction extending along a second direction (e.g., Y-direction) that is substantially perpendicular to the first direction. That is, the lengthwise direction of the first deep trenches 205A may be substantially perpendicular to the lengthwise direction of the second deep trenches 205B.

In FIG. 2, the DTC structure 120A may also include a plurality of capacitor groups 210A and a plurality of capacitor groups 210B (collectively referred to as “capacitor regions 210” hereinafter). Each of the capacitor groups 210A may include a plurality of capacitor units (see FIG. 7) formed in the first deep trenches 205A, and each of the capacitor groups 210B may include a plurality of capacitor units (see FIG. 7) formed in the second deep trenches 205B. In the illustrative example shown in FIG. 2, each capacitor group 210A includes five first deep trenches 205A, and each capacitor group 210B includes five second deep trenches 205B, while more or less number of the first deep trenches 205A and/or the second deep trenches 205B may also be applied. In greater detail, each capacitor group 210A includes five capacitor units formed in and over the first deep trenches 205A, and each capacitor group 210B includes five capacitor units formed in and over the second deep trenches 205B in accordance with some embodiments. As will be discussed in more detail later, the conductive layers and the dielectric layers in each of the capacitor groups 210 may continuously extend into the deep trenches 205. Thus, the capacitor units of the capacitor groups 210 may share the conductive layers and the dielectric layers.

The capacitor groups 210A and the capacitor groups 210B can be alternately arranged in multiple rows and multiple columns extending in the X-Y plane as shown in FIG. 2. In greater detail, the capacitor groups 210A and the capacitor groups 210B laterally alternate along the first direction (e.g., X-direction) in FIG. 2. Similarly, the capacitor groups 210A and the capacitor groups 210B laterally alternate along the second direction (e.g., Y-direction) in FIG. 2. Such arrangements of the capacitor groups 210 may effectively reduce the stress generated in the substrate 200, especially when a large area of the capacitor groups 210 is applied.

Conductive plugs 240 are formed to electrically couple the capacitor groups 210 to upper-level interconnects, such as the MLI structure 114 of the interposer 102 (See FIG. 1). In some embodiments, at least some of the conductive layers of the capacitor groups 210 comprise portions extending outside of the regions for the occupation of the deep trenches 205 (referred to as “core region 230” hereinafter) so as to allow the conductive plugs 240 to land thereon (referred to as “landing portions” hereinafter). That is, outer boundaries 220 of the capacitor groups 210 may be defined to include the landing portions of the conductive layers of the capacitor groups 210. For example, as shown in FIG. 2, the capacitor groups 210 may have rectangular outer boundaries 220, although other shapes may be applied for different design purposes. The outer boundaries 220 are larger than the core region 230 occupied by the deep trenches 205. In other words, in addition to the core region 230 occupied by the deep trenches 205, the capacitor groups 210 may each need a peripheral region 235 to allow the conductive plugs 240 to land thereon. In some embodiments, the conductive plugs 240 include a plurality of conductive plugs having different depths for landing on different layers of the conductive layers, which needs the landing portions of the different conductive layers spaced apart from each other. Accordingly, the capacitor groups 210 may need a large area for the peripheral region 235 for accommodating these landing portions of the conductive layers when multiple conductive layers are used.

In some embodiments, the peripheral region 235 may have a width W₂. The adjacent core regions 235 of the capacitor groups 210A and the capacitor groups 210B may have a spacing S1 (either along the first direction or the second direction), which may be about two times the width W₂. While any two of the first deep trenches 205A (or any two of the second deep trenches 205B) are separated by a spacing S2, the spacing S1 is at least about 5 times greater than the spacing S2, in accordance with some embodiments. When the critical dimension of the chips or packages continues to shrink, reducing the spacing S1 is desired to achieve a higher density of the capacitor groups.

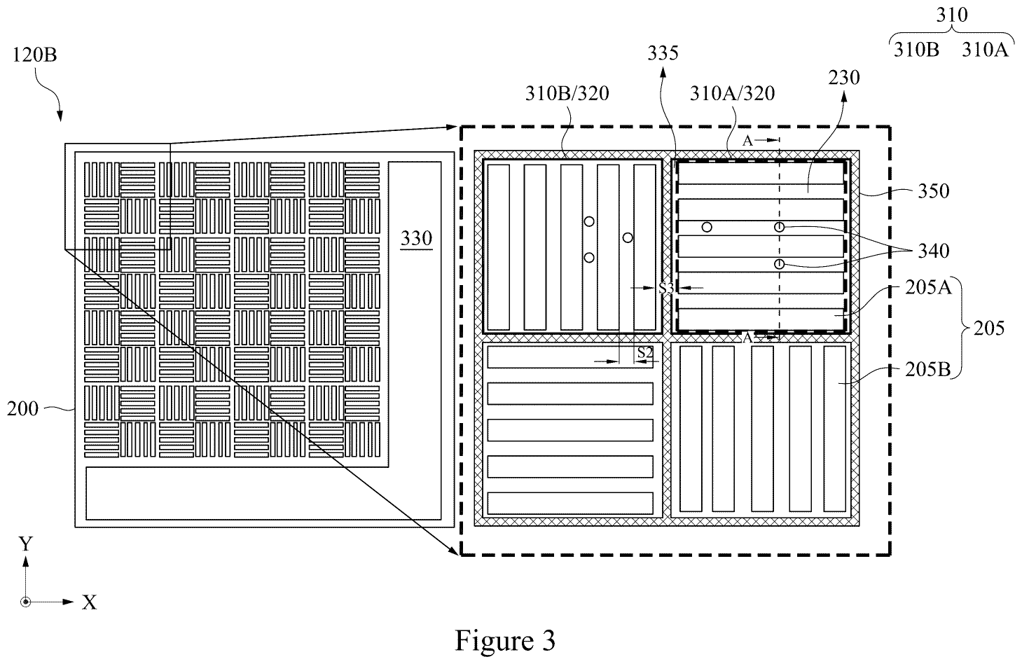

FIG. 3 is a top view of a deep trench capacitor (DTC) structure 120B, in accordance with some embodiments. The DTC structure 120B is similar to the DTC structure 120A shown in FIG. 2 and has a high density of capacitor groups. In FIG. 3, the dielectric layers and the conductive layers of the capacitor groups 310 are not shown for clarity purposes. In some embodiments illustrated in FIG. 3, conductive plugs 340 land within the core regions 230 of the capacitor groups 310, such as in core region 230 of the capacitor groups 310A and/or the core region 230 of the capacitor groups 310B, rather than landing on the peripheral regions 235 of the capacitor groups 210. In some embodiments, each of the conductive plugs 340 does not overlap the deep trenches 205 in the top view. For example, the conductive plugs 340 land between adjacent deep trenches 205 (e.g., between two adjacent first deep trenches 205A and/or between two adjacent the second deep trenches 205B). As such, the widths of the peripheral region 335 of the capacitor can be reduced. For example, in FIG. 3, the adjacent core regions 235 of the capacitor groups 210A and the capacitor groups 210B in the DTC structure 120B may have a spacing S3 (either along the first direction or the second direction). In some embodiments, the spacing S3 is reduced to be smaller than the spacing S2. In some embodiments, a ratio S3/S2 of the spacing S3 and the spacing S2 is in a range from about 0.5 to about 1.5. As such, the capacitor groups 310 may be arranged with a higher density than the capacitor groups 210 as illustrated in FIG. 2. As shown in FIG. 3, the area 330 represents that the DTC structure 120B can save as compared to the DTC structure 120A shown in FIG. 2.

Also refer to FIG. 3, in some embodiments, an isolation wall 350 is provided to sufficiently reduce or prevent signal interference between adjacent capacitor groups 210. The isolation wall 350 may be a close loop in a top view, and the close loop may include one more sub-close loops therein. The isolation wall 350 may be disposed between the peripheral regions 335 of the capacitor groups 310, or the outer boundaries 320 of the capacitor groups 210 can be defined by the isolation wall 350. For example, each of the capacitor groups 310 is laterally surrounded by the isolation wall 350, in accordance with some embodiments. As such, the capacitor groups 310 may be electrically isolated from each other by the isolation wall 350 (if they are not electrically coupled by upper-level interconnects).

FIGS. 4 to 7 illustrate a method for manufacturing the deep-trench-capacitor (DTC) structure at intermediate stages in accordance with some embodiments. In some embodiments, the method of FIGS. 4 to 7 illustrates a method for manufacturing the DTC structure 120B as described in FIG. 3. FIGS. 4 through 7 illustrate reference cross-section A-A′ illustrated in the DTC structure 120B, wherein the cross-section A-A′ is along a direction perpendicular to a longitudinal axis of the first deep trenches 205A illustrated in FIG. 3.

In FIG. 4, the substrate 200 includes a plurality of deep trenches 205 (e.g., first deep trenches 205A) and a plurality of mesas 401 interposed by two adjacent deep trenches 205. The deep trenches 205 may be formed by forming a patterned mask layer on the front side surface of the substrate 200. The pattern in the patterned mask layer may be transferred into an upper portion of the substrate 200. An optional pad dielectric layer (not shown) such as a silicon oxide pad layer may be formed on the front side surface, i.e., the top surface, of the substrate 200 prior to formation of the patterned mask layer. In an exemplary embodiment, the pad dielectric layer may include a silicon oxide layer with a thickness ranging from 20 nm to 100 nm, although thicker or thinner pad dielectric layers may be used.

The patterned mask layer may include a silicon nitride layer or a borosilicate glass (BSG) layer having a thickness in a range from 200 nm to 600 nm, although different materials and/or lesser or greater thicknesses may also be used for the optional pad dielectric layer and the patterned mask layer. The patterned mask layer may be formed by depositing a blanket mask layer, forming a lithographically patterned photoresist layer over the blanket mask layer, and by transferring the pattern in the lithographically patterned photoresist layer through the blanket mask layer using an anisotropic etch process such as a reactive ion etch process.

An anisotropic etch process may be performed to transfer the pattern in the patterned etch mask layer through an upper portion of the substrate 200 to form the deep trenches 205. For example, a reactive ion etch process using a combination of gases including HBr, NF₃, O₂, and SF₆ may be used to form the deep trenches 205. The depth of the deep trenches 205 may be in a range from 2 microns to 20 microns, such as from 3 microns to 10 microns, although deeper or shallower trenches may be used. In some embodiments, the deep trenches 205 have a depth-to-width ratio ranging from about 10 to about 200. Generally, the deep trenches 205 may be formed in the substrate 200, such as extending downward from a top surface of the substrate 200 into the substrate 200.

The photoresist layer may be removed prior to the anisotropic etch process for forming the deep trenches 205, or may be consumed during the anisotropic etch process for forming the deep trenches 205. The patterned etch mask layer and the optional dielectric pad layer may be subsequently removed, for example, by a respective isotropic etch process such as a wet etch process.

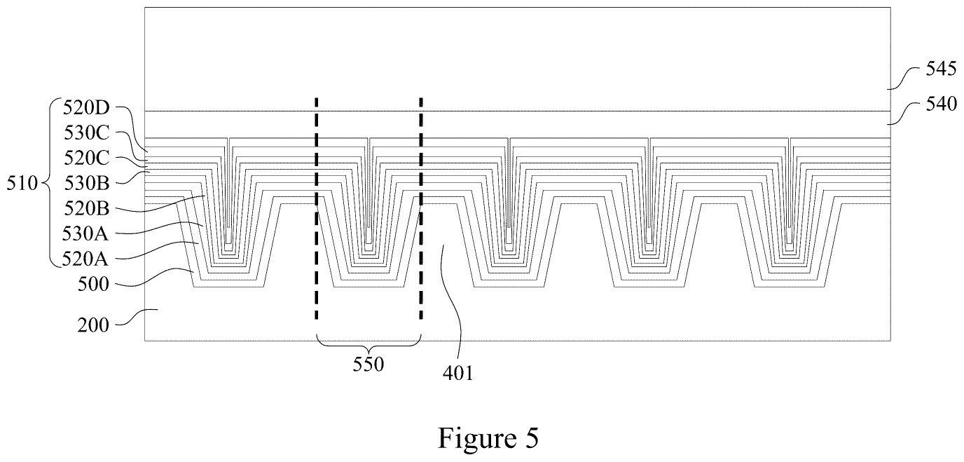

In FIG. 5, a dielectric liner 500 may be formed on the physically exposed surface of the substrate 200, including its top surface and sidewalls of the deep trenches 205. In some embodiments, the dielectric liner 500 includes a dielectric material able to provide electrical isolation between the substrate 200 and the conductive layers to be subsequently formed in the deep trenches 205. The dielectric liner 500 may include silicon oxide, silicon nitride, silicon oxynitride, a dielectric metal oxide, other suitable materials within the contemplated scope of disclosure may also be used. In the illustrative examples, the dielectric liner 500 may include a silicon oxide layer formed by thermal oxidation of surface portions of the substrate 200 that includes silicon. In some embodiments, the dielectric liner 500 is formed by CVD, ALD, PVD, or other suitable deposition methods. The thickness of the dielectric liner 500 may be in a range from 4 nm to 100 nm, although lesser and greater thicknesses may also be used.

In some embodiments, conductive layers and dielectric layers may be alternatively disposed in the deep trenches 205. For example, an alternating layer stack 510 of conductive layers 520A, 520B, 520C and 520D and node dielectric layers 530A, 530B and 530C may be formed in and over the deep trenches 205. In greater detail, the alternating layer stack 510 may include conductive layers 520A, 520B, 520C and 520D interlaced with the node dielectric layers 530A, 530B and 530C, respectively. The alternating layer stack 510 may continuously extend over the top surface of the substrate 200 (e.g., top surfaces of the mesas 401) and into each of the deep trenches 205.

Each of the conductive layers 520A, 520B, 520C and 520D may include a metallic material, which may comprise, and/or consist essentially of, a conductive metallic nitride, an elemental metal, or an intermetallic alloy. In some embodiments, the conductive layers 520A, 520B, 520C and 520D include and/or consist essentially of, a conductive metallic nitride material, which may be a metallic diffusion barrier material. For example, each conductive layer 520A, 520B, 520C and 520D may include, and/or may consist essentially of, a conductive metallic nitride material such as TiN, TaN, or WN. Other suitable materials within the contemplated scope of disclosure may also be used.

Use of a metallic diffusion barrier material for the conductive layers 520A, 520B, 520C and 520D may be advantageous because diffusion of metallic elements through the node dielectric layers 530A, 530B and 530C and/or through the dielectric liner 500 may cause deleterious effects for deep trench capacitors. The conductive layers 520A, 520B, 520C and 520D may be formed by a conformal deposition process such as PVD, CVD, ALD, or the like. The thickness of each conductive layer 520A, 520B, 520C and 520D may be in a range from 5 nm to 50 nm, such as from 10 nm to 30 nm, although lesser and greater thicknesses may also be used. In some embodiments, the conductive layers 520A, 520B, 520C and 520D have the same material composition and the same thickness. In some embodiments, the conductive layers 520A, 520B, 520C and 520D have the same material composition but have varying thicknesses. In some embodiments, the conductive layers 520A, 520B, 520C and 520D have different material compositions and the same thickness. In some embodiments, the conductive layers 520A, 520B, 520C and 520D have different material compositions and different thicknesses.

Each of node dielectric layers 530A, 530B and 530C may include a node dielectric material, which may be a dielectric metal oxide material having a dielectric constant greater than 7.9 (which is the dielectric constant of silicon nitride), i.e., a “high-k” dielectric metal oxide material, or may include silicon nitride. For example, the node dielectric layers 530A, 530B and 530C may each include a dielectric metal oxide material such as aluminum oxide, hafnium oxide, zirconium oxide, tantalum oxide, lanthanum oxide, an alloy or a silicate thereof, and/or a layer stack thereof. In some embodiments, the node dielectric layers 530A, 530B and 530C include aluminum oxide. Other suitable materials within the contemplated scope of disclosure may also be used.

Each of the node dielectric layers 530A, 530B and 530C may be formed by a conformal deposition process such as CVD or ALD. The thickness of the node dielectric layers 530A, 530B and 530C may be in a range from 1 nm to 20 nm, such as from 3 nm to 12 nm, although lesser and greater thicknesses may also be used. In some embodiments, the node dielectric layers 530A, 530B and 530C have the same material composition and the same thickness. In some embodiments, the node dielectric layers 530A, 530B and 530C have the same material composition but have varying thicknesses. In some embodiments, the node dielectric layer 530A, 530B and 530C have different material compositions and the same thickness. In some embodiments, the node dielectric layers 530A, 530B and 530C have different material compositions and different thicknesses.

While the present disclosure is described using an embodiment in which the alternating layer stack 510 of the conductive layers 520A, 520B, 520C and 520D and the node dielectric layers 530A, 530B and 530C include four conductive layers and three node dielectric layers, embodiments are expressly contemplated herein in which different numbers of conductive layers and different numbers of node dielectric layers may be used within the alternating layer stack 510. Generally, an alternating layer stack 510 may include at least three conductive layers interlaced with at least two node dielectric layers that may be formed in, and over, at least one deep trench 205 formed in the substrate 200. In some other embodiments, the total number of the conductive layers may be in a range from 3 to 16, such as from 4 to 8. The total number of the node dielectric layers may be one less than the total number of the conductive layers.

A capping dielectric material layer 540 and a dielectric fill material layer 545 may be optionally deposited over the alternating layer stack 510. The capping dielectric material layer 540 may include a same dielectric material as the node dielectric layers 530A, 530B, and 530C, and may have a thickness in a range from 1 nm to 20 nm, such as from 3 nm to 12 nm, although lesser and greater thicknesses may also be used.

The dielectric fill material layer 545 may be deposited on the capping dielectric material layer 540 or on the alternating layer stack 510 to fill the volumes of cavities that remain in the deep trenches 205. In one embodiment, the dielectric fill material layer 545 comprises, and/or consists essentially of, undoped silicate glass or a doped silicate glass. A planarization process, such as chemical mechanic polishing (CMP), may be performed on the as-deposited dielectric fill material layer 545 to provide the dielectric fill material layer 545 a planarized top surface.

After the dielectric fill material layer 545 is formed, the DTC structure 120B is formed. For example, the DTC structure 120B may include the dielectric liner 500, the alternating layer stack 510, the capping dielectric material layer 540, and the dielectric fill material layer 545. In some embodiments, the portions of the DTC structure 120B filled in and over the deep trenches 205 can be considered as capacitor units 550. In some embodiments, capacitor units 550 may have a similar width and a similar length with the corresponding deep trenches 205. Although FIG. 5 only shows that the capacitor units 550 are formed in the first deep trenches 205A, the capacitor units 550 may also be filled in the second deep trenches 205B. Accordingly, the capacitor units 550 may each have a lengthwise direction extending along the lengthwise direction of the deep trenches 205, such as along the first direction (e.g., X-direction) or along the second direction (e.g., Y-direction).

After forming the dielectric fill material layer 545, a dielectric layer 620 is formed over the dielectric fill material layer 545, in accordance with some embodiments. In some embodiments, the dielectric layer 620 includes one or more layers of dielectric materials. The dielectric layer 620 may include silicon oxide, Spin-On-Glass, Spin-on-Polymers, phosphosilicate glass (PSG), borophosphosilicate glass (BPSG), fluorosilicate glass (FSG), a low-k dielectric material such as SioₓC_{y}, combinations thereof, or the like, and may be formed by any suitable method, such as spin-on coating, CVD, ALD, a combination thereof, or the like.

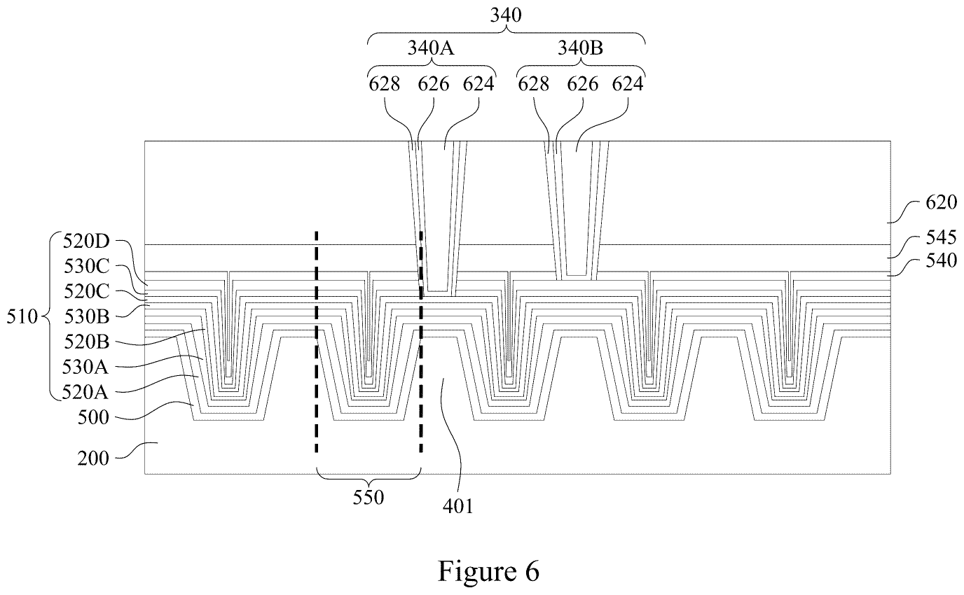

Referring to FIG. 6, conductive plugs 340 are formed in the dielectric layer 620 and electrically coupled to one or more of the conductive layers 520A-520D of the alternating layer stack 510, in accordance with some embodiments. The conductive plugs 340 may penetrate through the dielectric layer 620, the dielectric fill material layer 545, the capping dielectric material layer 540 to electrically couple to one or more of the conductive layers 520A-520D of the alternating layer stack 510. For example, in FIG. 6, two conductive plugs 340A and 340B having different depths are illustrated, although more or less conductive plugs with various depths can be used. In some embodiments, the conductive plugs 340A and 340B land on the conductive layers 520C and 520D, respectively. The conductive plugs 340 may laterally align to the mesas 410 to avoid damaging the capacitor units 550 in and over the deep trenches 205. In some embodiments, each of the conductive plugs 340 lands on different mesas 401. In some embodiments, more than one of the conductive plugs 340 land on the same mesa 401 (e.g., arranged in a row in the second direction when the mesa has a lengthwise direction along the second direction).

In some embodiments, the conductive plugs 340 include a conductive via 624, an optional barrier layer 626, and an insulating layer 628. The conductive plugs 340 may be formed using any suitable method, such as a damascene method, or the like. For example, the formation of the conductive plugs 340 may include forming openings in the respective dielectric layers; depositing the insulating layer 628 in the openings; etching the insulating layer 628 to expose the underlying layers; optionally depositing the barrier layer 626; and filling a conductive material in the opening to form the conductive vias 624. A seed layer may be deposited before forming the conductive material in accordance with some embodiments. In some embodiments, the conductive vias 624 includes copper, aluminum, tungsten, cobalt, alloys thereof, combinations thereof, or the like and may be formed using PVD, CVD, ALD, plating, a combination thereof, or the like. The barrier layer 626 comprises titanium, titanium nitride, tantalum, tantalum nitride, a combination thereof, or the like. In some embodiments, a chemical mechanical polishing (CMP) may be performed to remove excess materials of the dielectric layers, the barrier layers, the adhesion layers, the seed layers, and the conductive material overfilling the via holes. In some embodiments, additional dielectric layers (not shown) and additional metal interconnect structures (not shown) are formed over the dielectric layer 620 and the conductive plug 340.

Since the conductive plugs 340A and 340B land on respective conductive layers 520C and 520D, the openings for the conductive plugs 340A and 340B are formed with respective depths to expose the respective conductive layers 520C and 520D. One method to achieve this structure is to form the openings of conductive plugs 340A and 340B in separate processes. At least two patterning processes are applied to the dielectric layer 620 to form the respective openings. These patterning processes may each include one lithography process and one etch process. After the patterning processes, the respective openings are formed to expose respective conductive layers. For example, the opening for forming the conductive plug 340B may be formed after the opening for conductive plug 340A has been formed, or vice versa. After the openings for forming the conductive plug 340A and conductive plug 340B, the barrier layer 626 and the conductive via 624 are disposed in the openings for conductive plug 340A and conductive plug 340B in sequence.

In some embodiments, the etch process includes a dry etching process using an etchant containing fluorine, chlorine or a combination thereof, such as silicon tetrafluoride (SiF₄), silicon fluorine radical SiFₓ (x is 1, 2 or 3), silicon tetrachloride (SiCl₄), silicon chloride radical SiClₓ (x is 1, 2 or 3), or a combination thereof to etch the dielectric layer 620, the dielectric fill material layer 545, the capping dielectric material layer 540, and the node dielectric layers 530A, 530B and 530C. In some embodiments, the etching process also includes a dry etching process using an etchant containing Cl₂, BCl₃, other suitable etchant, or a combination thereof to etch the one or more conductive layers 520B-520D (if necessary). When openings are through multiple layers, the etchants may be changed according to the materials of the layers to be etched during a single etch process. For example, in the etch process of forming the opening for the conductive plugs 624A, after etching through the dielectric layers 620, 545, 540, the etchant may be changed to etchants suitable for etching the conductive layer 520D, and then the etchant may be further changed to etchants suitable for etching the node dielectric layer 530C.

In some embodiments, the insulating layer 628 is deposited in the openings for the conductive plugs 340A and 340B before forming the conductive vias 624 and the barrier layer 626. In FIG. 6, the insulating layer 628 is outer sidewalls of the conductive plugs 340 to provide electrical isolation from one or more of the conductive layers 520A-520D. For example, while the conductive plug 340A is designed to be electrically coupled to the conductive layer 520C, the insulating layer 628 can prevent the conductive via 624 of the conductive plug 340A from being electrically coupled to the conductive layer 520D.

Referring to FIG. 7, a dry etching process is performed to form a trench in the dielectric layer 620 and through the alternating layer stack 510. In some embodiments, the trench extends into the dielectric liner 500. In some embodiments, the trench extends into the mesa 401 of the substrate 200. An insulating layer 751 and an optional liner 752 may be deposited in the trench to form the isolation wall 350. The insulating layer 751 is formed of an insulating material, such as a low k dielectric material described for the dielectric layer 620, silicon oxide, silicon oxynitride, other suitable dielectric materials, or a combination thereof. In some embodiments, the insulating layer 751 is a material different from the dielectric layer 620, although similar or same material may be used. The liner 752 may include silicon nitride, silicon oxynitride, a dielectric metal oxide, or a combination thereof. In some embodiments, the liner 752 may have a material different from the material of the insulating layer 751 and/or the dielectric layer 620. In some embodiments, the dry etching process used to form the trench for the isolation wall 350 is similar to the etching process used to form the openings for the conductive plugs 340.

The isolation wall 350 may cut each of the dielectric liner 500, the alternating layer stack 510, the capping dielectric material layer 540, the dielectric fill material layer 545 and the dielectric layer 620 into separated portions. In some embodiments, as illustrated in FIG. 3, the isolation wall 350 may surround one or more capacitor groups 310. That is, the one or more capacitor groups 310 may be isolated from another one or more capacitor groups 310 (if not electrically connected by upper-level interconnects) because the conductive layers 520A-520D are cut by the isolation wall 350. In some embodiments, the isolation wall 350 has a width over at least 50% of the width of the top surface of the mesa 401 on which the isolation wall 350 stands, thereby providing sufficient isolation between two adjacent capacitor groups 310. In some embodiments, the isolation wall 350 covers at least half of the top surface of the mesa 401. The conductive plugs 340 and the isolation wall 350 may laterally align to different mesas 401 in this example. In some embodiments, the isolation wall 350 and one or more the conductive plugs 340 land on a same mesa 401 (e.g., arranged in a row in the second direction when the mesa has a lengthwise direction along the second direction).

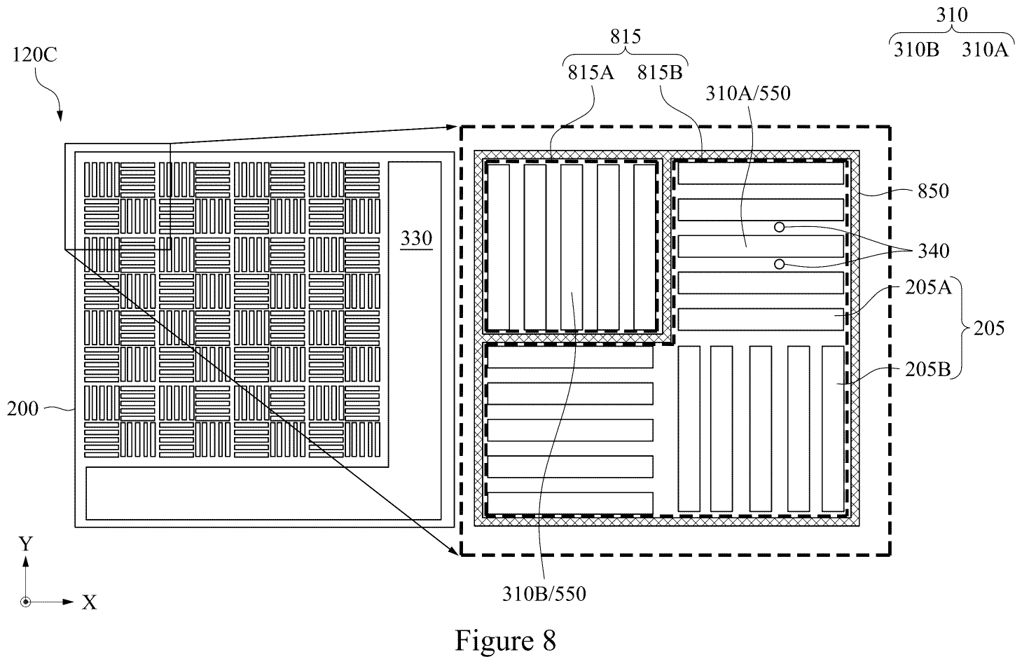

FIG. 8 is a top view of a deep trench capacitor (DTC) structure in accordance with some embodiments, wherein the conductive layers and the dielectric layers are not shown. The DTC structure 120C shown in FIG. 8 is similar to the DTC structure 120B shown in FIG. 3. In greater detail, the DTC unit cell can be considered as a bank of available capacitor groups 310, and in the DTC unit cell, any number of the capacitor groups 310 can form a capacitor with a capacitance proportional to the number of the capacitor groups 310. Once the design requirement of a chip to be connected to a DTC structure is known, the size and shapes of the DTC unit cell or the number of capacitor groups 310 to be included in the DTC unit cell can be calculated accordingly.

In FIG. 8, two DTC unit cells 815A and 815B are illustrated, and the boundaries of the DTC unit cells may be defined by the shape of the isolation wall 850. The DTC unit cell 815A may be formed of one capacitor group 310B. The DTC unit cell 815B may include three capacitor groups, such as two capacitor groups 310A and one capacitor group 310B. The illustrative examples of the DTC unit cells are for illustration only, and the DTC unit cell 815 may include any number capacitor groups and any shapes as long as the DTC unit cell 815 can be defined by a continuous isolation wall 850. The DTC unit cell 815 may have a larger capacitance when the DTC unit cell includes more numbers of the capacitor groups 310. In some embodiments, the DTC unit cell 815B includes three capacitor groups 310 and fifteen capacitor units 550, and the DTC unit cell 815A includes one capacitor group 310 and five capacitor units 550. The DTC unit cell 815B may include three times or more capacitance than the DTC unit cell 815A.

In some embodiments, the adjacent capacitor groups 310 within the DTC unit cell 815B are not cut by the isolation wall 850 so that the conductive layers 520A-520D and node dielectric layers 530A-520C, the capping dielectric material layer 540, the dielectric fill material layer 545, and the dielectric layer 620 continuously extend between the adjacent capacitor groups 310, such as extending over top surfaces of the substrate 200 between the adjacent capacitor groups 310. For example, the conductive layers 520A-520D and node dielectric layers 530A-530C, the capping dielectric material layer 540, the dielectric fill material layer 545, and the dielectric layer 620 continuously extend in the first direction between the capacitor group 310B and the capacitor group 310A in the DTC unit cell 815B. Also, the conductive layers 520A-520D and node dielectric layers 530A-530C, the capping dielectric material layer 540, the dielectric fill material layer 545, and the dielectric layer 620 continuously extend in the second direction between the capacitor group 310B and the capacitor group 310A in the DTC unit cell 815B. In some embodiments, the conductive layers 520A-520D and node dielectric layers 530A-530D, the capping dielectric material layer 540, the dielectric fill material layer 545, and the dielectric layer 620 are cut by the isolation wall 850 outside the DTC unit cell 815B (such as outside of close loop for the DTC unit cell 815B enclosed by the isolation wall 850), and thus the conductive layers 520A-520D and node dielectric layers 530A-530D disposed in the DTC unit cell 815B and the conductive layers 520A-520D and node dielectric layers 530A-530D disposed outside the DTC unit cell 815B are separated by the isolation wall 850.

One or more of the DTC unit cells 815 may contribute to a first functional block of a chip or a package, and other DTC unit cells 815 may contribute to a second functional block or other functional blocks of the chip or the package. In some embodiments, one or more of the DTC unit cells 815 contribute to a first chip or a first package, and other DTC unit cells 815 contribute to a second chip or a second package. Various applications of the DTC unit cells may be implemented.

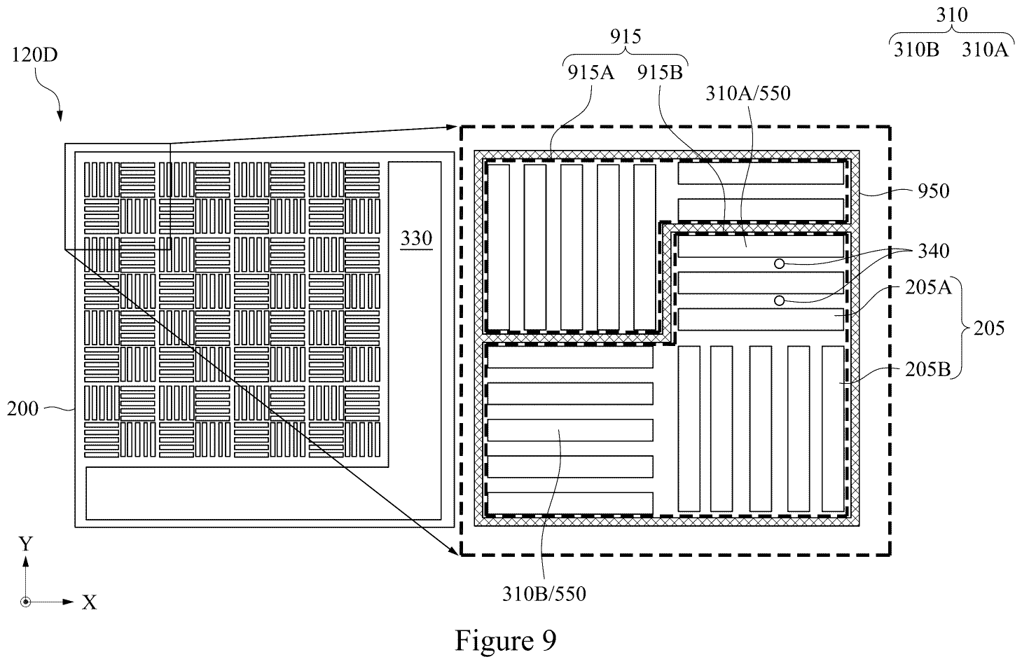

FIG. 9 is a top view of a deep trench capacitor (DTC) structure in accordance with some embodiments. The DTC structure 120D shown in FIG. 9 is similar to the DTC structure 120B shown in FIG. 3 or the DTC structure 120C shown in FIG. 8. The isolation wall 950 may be a close loop in the top view, and the close loop may include one or more sub-close loops therein. In some embodiments, the isolation wall 950 extends between two adjacent deep trenches 205 in a single capacitor group 310. In such embodiment, one DTC cell 915 can have capacitor units having a number, not just five times an integer. For example, the DTC structure 120D includes two DTC unit cells 915A and 915B. The DTC unit cell 915A may include one full capacitor group 310B and a divided portion of the capacitor group 310B. That is, one full capacitor group 310B, and one divided portion of the capacitor groups 310B is enclosed by the isolation wall 950 in the DTC unit cell 915A. For example, seven deep trenches 205 may be enclosed by the isolation wall 950 in the DTC unit cell 915A, and the DTC unit cell 915A has seven capacitor units 550. The DTC unit cell 915B may include one full capacitor group 310A, one full capacitor group 310B, and one divided portion of the capacitor group 310A. That is, one full capacitor group 310A, one full capacitor group 310B, and one divided portion of the capacitor group 310A are enclosed by the isolation wall 950 in the DTC unit cell 915B. For example, thirteen deep trenches 205 may be enclosed by the isolation wall 950 in the DTC unit cell 915B, and the DTC unit cell 915A has thirteen capacitor units 550. In such embodiments, one capacitor group 310 can be divided into separated portions to be contributed to different DTC unit cells, which allows the designer to have more flexibility to design the shapes of various DTC unit cells and how the DTC unit cells 915 to be used by individual chips. Redundant capacitor units 550 may be reduced or avoided, thereby allowing the designer to utilize the space of the DTC structure 120D more efficiently. The illustrative examples of the DTC unit cells 915 are for illustration only, and the DTC unit cells 915 may include any number of capacitor groups and any shapes as long as the DTC unit cells 915 can be defined by a continuous isolation wall 950.

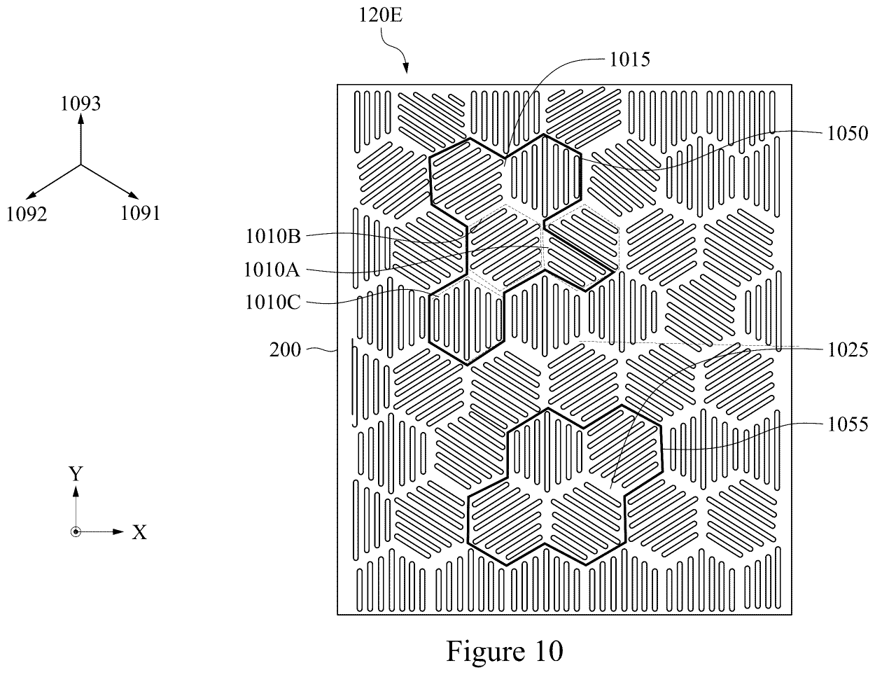

FIG. 10 is a top view of a deep trench capacitor (DTC) structure in accordance with some embodiments of the present application. The DTC structure 120E shown in FIG. 10 is similar to the DTC structure 120B shown in FIG. 3, the DTC structure 120C shown in FIG. 8 or the DTC structure 120D shown in FIG. 9. The DTC structure 120E includes a plurality of DTC unit cells, such as at least including the DTC unit cell 1015 and the DTC unit cell 1025. The DTC unit cell 1015 and the DTC unit cell 1025 may each include capacitor groups 1010A, 1010B and 1010C having a hexagonal boundary (a contour with a hexagon shape). Spacings between any two of the capacitor groups 1010A, 1010B and 1010C are the same, such as S2. The capacitor group 1010A has third deep trenches which are longitudinally oriented along a direction 1091. The capacitor group 1010B has fourth deep trenches which are longitudinally oriented along a direction 1092. The capacitor group 1010C has fifth deep trenches which are longitudinally oriented along a direction 1093. The directions 1091, 1092 and 1093 are different from each other. At least one of the capacitor groups 1010A, 1010B and 1010C has seven deep trenches in this example. The deep trenches in the capacitor groups 1010A, 1010B and 1010C are parallel to each other and extend in one of the three directions 1091, 1092, and 1093. The angle between any two of the three directions 1091, 1092, and 1093 is 120 degrees in the example. A central one of the deep trenches from each of capacitor groups 1010A, 1010B and 1010C is longer than the others. In other words, the central one of the deep trenches is the longest in each of the capacitor group 1010A, 1010B and 1010C. The two outermost trenches have the same length and are the shortest. Since the capacitor group 1010A, 1010B and 1010C have extending directions in three different directions 1091, 1092, and 1093, the stress caused by high-density trenches disposed in a large chip area has components in three directions, thereby reducing the warpage of the chip.

In FIG. 10, the shape and size of the DTC unit cells 1015 and 1025 are defined by the isolation wall 1050 and the isolation wall 1055, respectively. The isolation walls 1050 and 1055 are similar to the isolation wall 850 and may be formed of a similar material and formed in a similar manner. The isolation wall 1050 and 1055 may each be a close loop in the top view, and the close loops may each include one or more sub-close loops therein. In some embodiments, the isolation wall 1050 extends through the capacitor group 1010A by extending between two adjacent deep trenches in the capacitor group 1010A, thereby dividing the capacitor group 1010A. While the isolation wall 1055 only surrounds the outer boundaries of the capacitor groups 1010A, 1010B, and 1010C, the DTC unit cell 1025 includes full capacitor groups, such as four capacitor groups.

Embodiments of the present disclosure provide a semiconductor structure including a DTC structure having a high density. In the DTC structure, the conductive plugs may land on the conductive layers between adjacent deep trenches within capacitor groups. As such, the area of the peripheral regions can be effectively reduced. In some embodiments, the adjacent capacitor groups may be electrically isolated by an isolation wall. The isolation wall may allow the designer to design the shape and size of a DTC unit cell. The isolation wall may either surround outer boundaries of capacitor groups or extend through the capacitor groups, which allows a designer to have more flexibility to arrange the DTC unit cells more efficiently.

In an embodiment, a semiconductor structure includes a substrate having a plurality of deep trenches oriented in a first direction and a second direction and a plurality of mesas interposed by the deep trenches; a plurality of capacitor groups, wherein each of the capacitor groups includes a stack of conductive layers and node dielectric layers alternately disposed in the deep trenches and a first conductive plug disposed on a first layer of the conductive layers; and an isolation wall penetrating through the stack of the conductive layers and the node dielectric layers and into at least one of the mesas, the isolation wall being a close loop in a top view. In an embodiment, the semiconductor structure further includes a second conductive plug disposed on a second layer of the conductive layers, wherein the second layer of the conductive layers is below the first layer of the conductive layers. In an embodiment, the second conductive plug has a bottom in physical contact with the second layer of the conductive layers and a sidewall in physical contact with the first layer of the conductive layers. In an embodiment, the second conductive plug includes an insulating layer and a conductive via laterally surrounded by the insulating layer. In an embodiment, the isolation wall extends between two adjacent capacitor groups in a top view. In an embodiment, the isolation wall encloses two or more capacitor groups in a top view. In an embodiment, a first spacing between two adjacent capacitor groups is less than or equal to a second spacing between two adjacent deep trenches.

In an embodiment, a method for forming a semiconductor structure, the method includes forming a plurality of deep trenches in a substrate and mesas interposed by the deep trenches; forming a stack of conductive layers and node dielectric layers that are alternately disposed in the deep trenches; forming a first conductive plug connected to a first layer of the conductive layers; and forming an isolation wall penetrating through the stack of the conductive layers and the node dielectric layers and into at least one of the mesas, wherein the isolation wall is a close loop in a top view. In an embodiment, the method further includes forming a capping dielectric material layer on the stack; forming a dielectric fill material layer on the capping dielectric material layer, wherein the dielectric fill material layer has a planarized top surface; and forming a dielectric layer on the dielectric fill material layer. In an embodiment, forming the first conductive plug includes forming a first opening penetrating through a second layer of the conductive layers and one of the node dielectric layers; forming an insulating layer in the first opening, wherein the insulating layer is in physical contact with the first layer and the second layer of the conductive layers; etching the insulating layer in the first opening to expose the first layer of the conductive layers; and forming a conductive material in the first opening. In an embodiment, the method further includes a second conductive plug connected to the second layer of the conductive layers, wherein forming the second conductive plug includes: forming a second opening after forming the first opening and before forming the insulating layer; forming the insulating layer in the second opening; etching the insulating layer in the second opening to expose the second layer of the conductive layers; and forming the conductive material in the second opening. In an embodiment, the isolation wall extends between two adjacent capacitor groups in a top view. In an embodiment, forming the isolation wall is after forming the first conductive plug.

In an embodiment, a semiconductor structure includes a substrate including a first number of first deep trenches oriented in a first direction and the first number of second deep trenches oriented in a second direction, wherein the first number is a positive integer; a first capacitor group formed on the first deep trenches, the first capacitor group including: a first stack of first conductive layers and first node dielectric layers alternately disposed in the first number of the first deep trenches; and a first conductive plug disposed on one of first the conductive layers; a second capacitor group formed on the second deep trenches, the second capacitor group including: a second stack of second conductive layers and second node dielectric layers alternately disposed in the first number of the second deep trenches; and a second conductive plug disposed on one of the second conductive layers; and an isolation wall being a close loop enclosing the first capacitor group and a first portion of the second capacitor group in a top view, wherein the first stack of the first conductive layers and the first node dielectric layers is separated from the second stack of the second conductive layers and the second node dielectric layers by the isolation wall outside the close loop. In an embodiment, the isolation wall includes a first portion extending between two adjacent second deep trenches in the top view. In an embodiment, the isolation wall further includes a second portion extending two adjacent ones of the first deep trenches and the second deep trenches in the top view. In an embodiment, the isolation wall encloses the first number of the second deep trenches and a second number of the first deep trenches in the top view, wherein the second number is a positive integer and smaller than the first number. In an embodiment, the substrate further includes the first number of third deep trenches oriented in the first direction, wherein the first number of the third deep trenches have a gap with the first deep trenches in the first direction, wherein the isolation wall further encloses the first number of the third deep trenches in the top view. In an embodiment, the first conductive plug and the second conductive plug have different depths. In an embodiment, the first conductive plug does not overlap the first deep trenches in the top view.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor structure, comprising:
a substrate having a plurality of deep trenches oriented in a first direction and a second direction and a plurality of mesas interposed by the deep trenches;
a plurality of capacitor groups, each of the capacitor groups comprising:
a stack of conductive layers and node dielectric layers alternately disposed in the deep trenches; and
a first conductive plug disposed on a first layer of the conductive layers; and
an isolation wall penetrating through the stack of the conductive layers and the node dielectric layers and into at least one of the mesas, the isolation wall being a close loop in a top view.

2. The semiconductor structure of claim 1, further comprising:
a second conductive plug disposed on a second layer of the conductive layers, wherein the second layer of the conductive layers is below the first layer of the conductive layers.

3. The semiconductor structure of claim 2, wherein the second conductive plug has a bottom in physical contact with the second layer of the conductive layers and a sidewall in physical contact with the first layer of the conductive layers.

4. The semiconductor structure of claim 3, wherein the second conductive plug comprises an insulating layer and a conductive via laterally surrounded by the insulating layer.

5. The semiconductor structure of claim 1, wherein the isolation wall extends between two adjacent capacitor groups in a top view.

6. The semiconductor structure of claim 1, wherein the isolation wall encloses two or more capacitor groups in a top view.

7. The semiconductor structure of claim 1, wherein a first spacing between two adjacent capacitor groups is less than or equal to a second spacing between two adjacent deep trenches.

8. A method for forming a semiconductor structure, comprising:
forming a plurality of deep trenches in a substrate and mesas interposed by the deep trenches;
forming a stack of conductive layers and node dielectric layers that are alternately disposed in the deep trenches;
forming a first conductive plug connected to a first layer of the conductive layers; and
forming an isolation wall penetrating through the stack of the conductive layers and the node dielectric layers and into at least one of the mesas, wherein the isolation wall is a close loop in a top view.

9. The method of claim 8, further comprising:
forming a capping dielectric material layer on the stack;
forming a dielectric fill material layer on the capping dielectric material layer, wherein the dielectric fill material layer has a planarized top surface; and
forming a dielectric layer on the dielectric fill material layer.

10. The method of claim 8, wherein forming the first conductive plug comprises:
forming a first opening penetrating through a second layer of the conductive layers and one of the node dielectric layers;
forming an insulating layer in the first opening, wherein the insulating layer is in physical contact with the first layer and the second layer of the conductive layers;
etching the insulating layer in the first opening to expose the first layer of the conductive layers; and
forming a conductive material in the first opening.

11. The method of claim 10, further comprising a second conductive plug connected to the second layer of the conductive layers, wherein forming the second conductive plug comprises:
forming a second opening after forming the first opening and before forming the insulating layer;
forming the insulating layer in the second opening;
etching the insulating layer in the second opening to expose the second layer of the conductive layers; and
forming the conductive material in the second opening.

12. The method of claim 8, wherein the isolation wall extends between two adjacent capacitor groups in a top view.

13. The method of claim 8, wherein forming the isolation wall is after forming the first conductive plug.

14. A semiconductor structure, comprising:
a substrate comprising a first number of first deep trenches oriented in a first direction and the first number of second deep trenches oriented in a second direction, wherein the first number is a positive integer;
a first capacitor group formed on the first deep trenches, the first capacitor group comprising:
a first stack of first conductive layers and first node dielectric layers alternately disposed in the first number of the first deep trenches; and
a first conductive plug disposed on one of first the conductive layers;
a second capacitor group formed on the second deep trenches, the second capacitor group comprising:
a second stack of second conductive layers and second node dielectric layers alternately disposed in the first number of the second deep trenches; and
a second conductive plug disposed on one of the second conductive layers; and
an isolation wall being a close loop enclosing the first capacitor group and a first portion of the second capacitor group in a top view, wherein the first stack of the first conductive layers and the first node dielectric layers is separated from the second stack of the second conductive layers and the second node dielectric layers by the isolation wall outside the close loop.

15. The semiconductor structure of claim 14, wherein the isolation wall comprises a first portion extending between two adjacent second deep trenches in the top view.

16. The semiconductor structure of claim 15, wherein the isolation wall further comprises a second portion extending two adjacent ones of the first deep trenches and the second deep trenches in the top view.

17. The semiconductor structure of claim 15, wherein the isolation wall encloses the first number of the second deep trenches and a second number of the first deep trenches in the top view, wherein the second number is a positive integer and smaller than the first number.

18. The semiconductor structure of claim 17, wherein the substrate further comprises the first number of third deep trenches oriented in the first direction, wherein the first number of the third deep trenches have a gap with the first deep trenches in the first direction, wherein the isolation wall further encloses the first number of the third deep trenches in the top view.

19. The semiconductor structure of claim 15, wherein the first conductive plug and the second conductive plug have different depths.

20. The semiconductor structure of claim 15, wherein the first conductive plug does not overlap the first deep trenches in the top view.
